(19) United States
(12) Patent Application Publication
(10) Pub. No.: US 2026/0211576 A1
(43) Pub. Date: Jul. 23, 2026

(54) MEMORY CONTROLLER, STORAGE DEVICE AND CALCULATION METHOD THEREOF

(71) Applicant: SK hynix Inc., Icheon-si (KR)

(72) Inventors: Soon Hyun KWON, Icheon-si (KR); Jin Sub KIM, Icheon-si (KR)

(21) Appl. No.: 19/213,339

(22) Filed: May 20, 2025

(30) Foreign Application Priority Data
Jan. 23, 2025 (KR) 10-2025-0010155

(51) Int. Cl. G06F 3/06

(52) U.S. Cl. CPC G06F 3/0655; G06F 3/0604; G06F 3/0679

(57) ABSTRACT

The present disclosure relates to a method for setting the operation clock according to the temperature and a device thereof. Disclosed is a memory controller, including: a first interface (e.g., a host interface) configured to perform a data communication with a first external device (e.g., a host or an external device); a second interface (e.g., a memory interface) configured to generate a signal controlling an operation of a second external device; and at least one processor configured to determine an operation clock of the second external device (e.g., a memory) based on a temperature of the second external device.

### CROSS REFERENCE TO RELATED APPLICATION

The present application claims the benefit of priority under 35 U.S.C. § 119 (a) to Korea Patent Application No. 10-2025-0010155, filed Jan. 23, 2025 in the Korean Intellectual Property Office, which is incorporated in its entirety herein for all purposes by this reference.

### FIELD

Various embodiments relate to a memory controller, a storage device and an operation method thereof, more particularly, to a memory controller, a storage device and a method of operation for improving operational performance according to temperature.

### BACKGROUND

An electronic device is designed to perform a certain operation and may include all components and devices configured to perform the operation when power is supplied thereto. For example, the electronic device may include a storage device, a smartphone, a cleaner, a computer, a server, a battery management system, a nuclear facility control device, etc.

All electronic devices have a maximum allowable temperature range set so as to secure reliability and durability, and the temperature of the electronic device may increase over the course of performing an operation. The maximum allowable temperature range may be exceeded as the temperature of the electronic device increases, and therefore, many electronic devices have measures to decrease the temperature when it reaches a certain temperature and higher.

In this regard, reduction of a velocity of an operation clock can be used, however, performance deterioration occurs when reducing the clock in use.

For example, a storage device is a device capable of storing data based on a request of an external device such as a mobile terminal including a computer, a smartphone, and a tablet, and various electronic devices. Such a storage device operates within a certain temperature range, and when the storage device exceeds a maximum temperature, the storage device reduces the velocity of the operation clock by performing thermal throttling. A value of the operation clock at the time of the thermal throttling may be a random set value. As such, the operation clock set as a random set value may not optimize the operational performance of the storage device.

### SUMMARY

Various embodiments of the present disclosure provide a storage device that recognizes the above-described problem and sets the operation clock according to a temperature based on a genetic algorithm in order to optimize performance of the electronic device or the storage device.

The technical problem to be achieved by the present disclosure is not limited to the above-mentioned technical problem, and other technical problems that are not mentioned will be clearly understood by ordinary-skilled persons in the art to which the present disclosure pertains from the following description.

One embodiment is a memory controller, including: a first interface (e.g., a host interface) configured to perform a data communication with a first external device (e.g., a host or an external device); a second interface (e.g., a memory interface) configured to generate a signal controlling an operation of a second external device; and at least one processor configured to determine an operation clock of the second external device (e.g., a memory) based on a temperature of the second external device.

According to various embodiments of the present disclosure, the at least one processor may set a clock control table of which an operation clock according to a temperature is set with respect to each of a plurality of dies provided in the second external device; determine fitness corresponding to performance of each die with respect to each of the plurality of dies; and update the clock control table based on the fitness determined with respect to each of the plurality of dies.

According to various embodiments of the present disclosure, the at least one processor may determine fitness with respect to each of the plurality of dies whenever a preset condition is satisfied, and update the clock control table based on the fitness determined with respect to each of the plurality of dies.

According to various embodiments of the present disclosure, the at least one processor may measure a latency, which is a time period from a time point when fulfillment of a read operation or a program operation starts to a time point when the fulfillment is completed per the plurality of dies; and determine an inverse number of the latency by using the fitness with respect to each of the plurality of dies.

According to various embodiments of the present disclosure, wherein the at least one processor may measure a latency, which is a time period from a time point when fulfillment of a read operation or a program operation starts to a time point when the fulfillment is completed per the plurality of dies, a plurality of times for a certain period; determine an average latency by averaging the plurality of latencies measured per the plurality of dies for the certain period; and determine an inverse number of the average latency by using the fitness with respect to each of the plurality of dies.

According to various embodiments of the present disclosure, the at least one processor may change the certain period based on a change amount of a measured temperature and/or a number of times of a change of a measured temperature.

According to various embodiments of the present disclosure, the at least one processor may compare the fitness determined with respect to each of the plurality of dies; select two dies having highest fitness among the plurality of dies as parent dies; keep the clock control table unchanged with respect to the parent dies; select remaining dies except the parent dies among the plurality of dies as progeny dies; and update the clock control table of each of the progeny dies based on the clock control table of the parent dies.

According to various embodiments of the present disclosure, the at least one processor may update the clock control table of each of the progeny dies by cross-over of the clock control table of the parent dies.

According to various embodiments of the present disclosure, the at least one processor may additionally update the clock control table of each of the progeny dies by inserting a mutation stochastically into the clock control table of each of the progeny dies.

According to various embodiments of the present disclosure, the at least one processor may perform the cross-over by bitwise-calculating two values corresponding to an operation clock set per temperature in the clock control table of the parent dies; and the bitwise calculation may be one among a NAND calculation per bit, an XOR calculation per bit, an AND calculation per bit, and an OR calculation per bit.

According to various embodiments of the present disclosure, the at least one processor may perform the cross-over by selecting one among two values corresponding to an operation clock set per temperature in the clock control table of the parent dies and bitwise-calculating the selected one value, and the bitwise calculation may be one among a NOT calculation per bit, a calculation of a bit left shift as many as a preset quantity of bits, a calculation of bit right shift as many as a preset quantity of bits, a calculation of adding a preset first value, and a calculation of subtracting a preset second value.

According to various embodiments of the present disclosure, the at least one processor may perform the cross-over by bitwise-calculating only a preset number of least significant bits among a plurality of bits representing a value corresponding to the operation clock, and keeping remaining bits unchanged.

According to various embodiments of the present disclosure, the at least one processor may determine whether to insert the mutation with respect to each of a plurality of bits representing a value corresponding to the operation clock based on a preset probability; and invert a bit value of the bit determined to be inserted with the mutation.

Another embodiment is a method for operating a memory controller, including: setting a clock control table of which an operation clock according to a temperature is set with respect to each of a plurality of dies provided in a memory; determining fitness corresponding to performance of each die with respect to each of the plurality of dies; and updating the clock control table based on the fitness determined with respect to each of the plurality of dies.

According to various embodiments of the present disclosure, the determining fitness with respect to each of the plurality of dies may include: measuring a latency, which is a time from a time point when fulfillment of a read operation or a program operation starts to a time point when the fulfillment is completed per the plurality of dies; and determining an inverse number of the latency by using the fitness with respect to each of the plurality of dies.

According to various embodiments of the present disclosure, the determining fitness with respect to each of the plurality of dies may include: measuring a latency, which is a time from a time point when fulfillment of a read operation or a program operation starts to a time point when the fulfillment is completed, per the plurality of dies, for a plurality of times for a certain period; determining an average latency by averaging the plurality of latencies measured per the plurality of dies for the certain period; and determining an inverse number of the average latency by using the fitness with respect to each of the plurality of dies.

According to various embodiments of the present disclosure, the determining fitness with respect to each of the plurality of dies further may include: changing the certain period based on a change amount of a measured temperature and/or a number of times of a change of a measured temperature.

According to various embodiments of the present disclosure, the updating the clock control table based on the fitness determined with respect to each of the plurality of dies may include: comparing the fitness determined with respect to each of the plurality of dies; selecting two dies having highest fitness among the plurality of dies as parent dies; keeping the clock control table unchanged with respect to the parent dies; selecting remaining dies except the parent dies among the plurality of dies as progeny dies; and updating the clock control table of each of the progeny dies based on the clock control table of the parent dies.

According to various embodiments of the present disclosure, the updating the clock control table of each of the progeny dies based on the clock control table of the parent dies may include: performing cross-over of the clock control table of the parent dies.

According to various embodiments of the present disclosure, the updating the clock control table of each of the progeny dies based on the clock control table of the parent dies may further include: inserting a mutation stochastically into the clock control table determined by performing the cross-over.

According to various embodiments of the present disclosure, the performing cross-over of the clock control table of the parent dies may include: bitwise-calculating two values corresponding to an operation clock set per temperature in the clock control table of the parent dies; and the bitwise calculation may be one among a NAND calculation per bit, an XOR calculation per bit, an AND calculation per bit, and an OR calculation per bit.

According to various embodiments of the present disclosure, the performing cross-over of the clock control table of the parent dies may include: selecting one among two values corresponding to an operation clock set per temperature in the clock control table of the parent dies; and bitwise-calculating the selected one value, and the bitwise calculation may be one among a NOT calculation per bit, a calculation of a bit left shift as many as a preset quantity of bits, a calculation of bit right shift as many as a preset quantity of bits, a calculation of adding a preset first value, and a calculation of subtracting a preset second value.

According to various embodiments of the present disclosure, the performing cross-over of the clock control table of the parent dies may include: bitwise-calculating only a preset number of least significant bits among a plurality of bits representing a value corresponding to the operation clock; and keeping remaining bits unchanged.

According to various embodiments of the present disclosure, the inserting a mutation stochastically into the clock control table determined by performing the cross-over may include: determining whether to insert the mutation with respect to each of a plurality of bits representing a value corresponding to the operation clock based on a preset probability; and inverting a bit value of the bit determined to be inserted with the mutation.

Still another embodiment is a storage device, including: a memory having a plurality of dies; and a memory controller configured to generate a signal controlling an operation of the memory and to determine an operation clock of each of the plurality of dies based on a temperature of each of the plurality of dies, and the memory controller may set a clock control table of which an operation clock according to a temperature per the plurality of dies is set; determine fitness corresponding to performance of each die with respect to each of the plurality of dies; and update the clock control table based on the fitness determined with respect to each of the plurality of dies.

According to various embodiments of the present disclosure, the memory controller may measure a latency, which is a time from a time point when fulfillment of a read operation or a program operation starts to a time point when the fulfillment is completed per the plurality of dies; and determine an inverse number of the latency by using the fitness with respect to each of the plurality of dies.

According to various embodiments of the present disclosure, the memory controller may measure a latency, which is a time from a time point when fulfillment of a read operation or a program operation starts to a time point when the fulfillment is completed per the plurality of dies, a plurality of times for a certain period; determine an average latency by averaging the plurality of latencies measured per the plurality of dies for the certain period; and determine an inverse number of the average latency by using the fitness with respect to each of the plurality of dies.

According to various embodiments of the present disclosure, the memory controller may change the certain period based on a change amount of a measured temperature and/or a number of times of a change of a measured temperature.

According to various embodiments of the present disclosure, the memory controller may compare the fitness determined with respect to each of the plurality of dies; select two dies having highest fitness among the plurality of dies as parent dies; keep the clock control table unchanged with respect to the parent dies; select remaining dies except the parent dies among the plurality of dies as progeny dies; and update the clock control table of each of the progeny dies based on the clock control table of the parent dies.

According to various embodiments of the present disclosure, it is possible to allow an electronic device or a storage device to provide optimized performance by setting an optimized operation clock velocity according to a temperature of an electronic device or a storage device.

### BRIEF DESCRIPTION OF THE DRAWINGS

FIG. 1 is a schematic configuration diagram of a storage device according to embodiments of the present disclosure.

FIG. 2 is a view illustrating an operation clock according to an initially set temperature according to embodiments of the present disclosure.

FIG. 3 is a flowchart illustrating a method for optimizing a clock control table according to embodiments of the present disclosure.

FIG. 4 is a flowchart illustrating a method for updating a clock control table based on fitness according to various embodiments of the present disclosure.

FIGS. 5A to 5C are views illustrating examples of updating a clock control table based on fitness obtained as a result of applying a method of FIG. 4.

FIGS. 6 and 7 are views illustrating examples of cross-overs according to various embodiments of the present disclosure.

FIG. 8 is a view illustrating an example of a mutation according to embodiments of the present disclosure.

### DETAILED DESCRIPTION

Hereinafter, exemplary embodiments of the present disclosure will be described in further detail with reference to the accompanying drawings.

Descriptions provided hereinafter will be centered on a storage device, however it is apparent that methods proposed by the present disclosure may be used in all electronic devices that include a storage device.

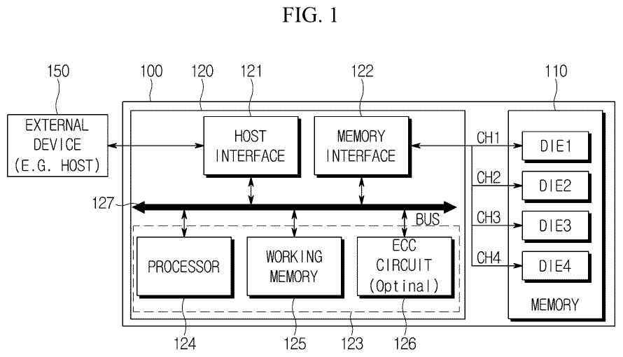

FIG. 1 is a schematic configuration diagram of a storage device according to embodiments of the present disclosure.

Referring to FIG. 1, a storage device 100 according to embodiments of present disclosure may include a memory 110 that stores data and a controller 120 that controls the memory 110.

The memory 110 may include a plurality of memory dies DIE1 to DIE4. The plurality of memory dies operates in response to control of the controller 120 through a plurality of channels CH1 to CH4. Here, an operation of the memory 110 may include, for example, a read operation, a program operation (also referred to as “write operation”), and an erasure operation.

Referring to an embodiment of FIG. 1, each of the plurality of channels CH1 to CH4 may have at least one memory die connected thereto. When a plurality of dies is connected to one channel, one read command or program command may be applied to only one die from among the plurality of dies. That is, when a plurality of dies is connected to one channel, simultaneous access to the plurality of dies is not possible, and one command may be applied to one die only. Therefore, in contrast embodiments hereinafter will describe a storage device in which only one memory die is connected to each of the plurality of channels CH1 to CH4.

One channel may transmit an operation command sequentially to a connected memory die, or may transmit data sequentially from the memory die to the controller 120. In addition, the plurality of memory dies connected respectively to the plurality of channels, having received operation commands through respective channels, may perform the operation according to the received operation command at the same time.

According to embodiments, each memory die may include at least one or more planes. In addition, a plane may include a plurality of memory blocks.

A memory 110 may be implemented in various types of memory, such as a NAND flash memory, 3D NAND flash memory, a NOR flash memory, resistive random-access memory (RRAM), a phase-change memory (PRAM), magnetoresistive random access memory (MRAM), a ferroelectric random access memory (FRAM), or a spin transfer torque random access memory (STT-RAM) and the like.

A memory 110 may be implemented with a three-dimensional array structure. Embodiments of the present disclosure may be applied not only to a flash memory in which a charge storage layer is formed with a conductive floating gate, but also to a charge trap type flash (CTF) in which a charge storage layer is formed with an insulating film.

The memory 110 may receive commands and addresses from the controller 120, and may access a region selected by an address from among memory cell arrays (not illustrated). That is, the memory 110 may perform an operation indicated by a command with respect to a region selected by an address.

For example, the memory 110 may perform a program operation, a read operation, an erasure operation, and the like. In relation to the above, during a program operation, the memory 110 may program data into a region selected by an address. During a read operation, the memory 110 may read data from a region selected by an address. During an erasure operation, the memory 110 may erase data stored in a region selected by an address.

The controller 120 may control write (program), read, erasure, and background operations with respect to the memory 110. Here, a background operation may include one or more among garbage collection (GC), wear leveling (WL), read reclaim (RR), and bad block management (BBM) operations.

The controller 120 may control the operation of the memory 110 according to a request of an external device (e.g., a host) located outside the storage device 100, or the controller 120 may control the operation of the memory 110 regardless of a request of an external device.

An external device may be a computer, a UMPC (Ultra Mobile PC), a workstation, PDA (Personal Digital Assistant), a tablet, a mobile phone, a smart phone, an e-book, a PMP (portable multimedia player), a portable game machine, a navigation device, a black box, a digital camera, a DMB (Digital Multimedia Broadcasting) player, a smart television, a digital audio recorder, a digital audio player, a digital picture recorder, a digital picture player, a digital video recorder, a digital video player, a storage constituting a data center, one of various electronic devices constituting a home network, one of various electronic devices constituting a computer network, one of various electronic devices constituting a telematics network, an RFID (radio frequency identification) device, and a mobile device (e.g. vehicle, robot, drone) that travels on the ground, water or air under human control or autonomously travels.

The external device may include at least one operating system (OS). The operating system may generally manage and control functions and calculations of an external device, and provide mutual operations between the external device and the storage device 100. The operating system may be divided into a general operating system and a mobile operating system according to the mobility of an external device.

Meanwhile, the controller 120 and an external device may be separate devices. In some cases, the controller 120 and an external device may be implemented as an integrated device. Hereinafter, for convenience of description, examples in which the controller 120 and an external device are separate devices will be described.

Referring to FIG. 1, the controller 120 may include a host interface 121, a memory interface 122, a control circuit 123, and the like.

The host interface 121 provides an interface for communication with an external device. For example, the host interface 121 may provide an interface that uses at least one among various interface protocols such as a Universal Serial Bus (USB) protocol, a multimedia card (MMC) protocol, a peripheral component interconnection (PCI) protocol, a PCI-express (PCI-E) protocol, an Advanced Technology Attachment (ATA) protocol, a Serial-ATA protocol, a Parallel-ATA protocol, a small computer small interface (SCSI) protocol, an enhanced small disk interface (ESDI) protocol, an Integrated Drive Electronics (IDE) protocol, a proprietary protocol, and the like.

The control circuit 123 may receive a command through the host interface 121 when receiving a command from an external device and may perform an operation of processing the received command.

The memory interface 122 may be connected to the memory 110 to provide an interface for communication with the memory 110. That is, the memory interface 122 may be configured to provide an interface between the memory 110 and the controller 120 in response to control of the control circuit 123.

The control circuit 123 may control an operation of the memory 110 by performing overall control of the controller 120. To this end, according to embodiments of the disclosure, the control circuit 123 may include one or more among a processor 124 and a working memory 125, and may include an error detection and correction circuit (ECC Circuit) 126 optionally.

The processor 124 may control all operations of the controller 120, and perform a logic operation. The processor 124 may communicate with an external device through the host interface 121 and may communicate with the memory 110 through the memory interface 122.

The processor 124 may perform a function of a flash translation layer (FTL). The processor 124 may translate a logical block address (LBA) provided by a host into a physical block address (PBA) through a flash translation layer (FTL). Using a mapping table, the flash translation layer (FTL) may receive a logical block address (LBA) and translate it into a physical block address (PBA).

There are various address mapping methods which may be employed by the flash translation layer according to the mapping unit. Typical address mapping methods include a page mapping method, a block mapping method, and a hybrid mapping method.

The processor 124 may randomize data received from an external device. For example, the processor 124 may randomize data received from an external device using a set randomizing seed. The randomized data may be provided to the memory 110 and programmed into the memory cell array of the memory 110.

The processor 124 may derandomize data received from the memory 110 during a read operation. For example, the processor 124 may derandomize data received from the memory 110 using a derandomizing seed. The derandomized data may be output to an external device.

The processor 124 may control the operation of the controller 120 by executing firmware. In other words, the processor 124 may control overall operations of the controller 120 and execute (drive) firmware stored in the working memory 125 at the time of booting. Hereinafter, an operation of the storage device 100 described by embodiments of the present disclosure may be implemented by the processor 124 executing firmware in which the corresponding operation is defined.

Firmware is a program executed in the storage device 100 to drive the storage device 100 and may include various functional layers. For example, the firmware may include binary data in which codes for executing each of the above-mentioned functional layers are defined.

For example, the firmware may include a flash translation layer (FTL) that performs a translation function between a logical address that an external device has for the storage device 100 and a physical address of the memory 110; a host interface layer (HIL) that receives and translates a command that the external device has for the storage device 100 and delivers it to the flash translation layer (FTL); and a flash interface layer (FIL) that delivers a command instructed by the flash translation layer (FTL) to the memory 110.

Such firmware, for example, may be loaded into the working memory 125 from the memory 110 or a separate non-volatile memory (e.g., ROM, NOR Flash) located outside the memory 110. When executing a booting operation after power is turned on, the processor 124 may first load all or part of the firmware into the working memory 125.

The processor 124 may perform logic operations defined in firmware loaded into the working memory 125 to control the overall operations of the controller 120. The processor 124 may store, in the working memory 125, a result of performing a logic operation defined in the firmware. The processor 124 may control the controller 120 to generate a command or signal according to a result of performing a logic operation defined in the firmware. When part of the firmware, in which a logical operation to be performed is defined, is not loaded into the working memory 125, the processor 124 may generate an event (e.g., interrupt) for loading the corresponding part of the firmware into the working memory 125.

The processor 124 may load meta data, required to drive the firmware, from the memory 110. Meta data is data for managing the memory 110 and may include management information about user data stored in the memory 110.

The firmware may be updated while the storage 100 is being produced or while the storage device 100 is running. The controller 120 may download new firmware from an external device of the storage device 100 and update the existing firmware to a new firmware.

The working memory 125 may store firmware, program codes, commands, or pieces of data necessary to drive the memory controller 120. The working memory 125 may include at least one or more among, for example, a static RAM (SRAM), a dynamic RAM (DRAM), and/or a synchronous RAM (SDRAM) as a volatile memory.

The error detection/correction circuit 126 may be configured to detect error bits of target data, and to correct the detected error bit(s) using an error correction code. For example, the target data may be data stored in the working memory 125, data read from the memory 110, or the like.

The error detection/correction circuit 126 may be implemented to decode data using the error correction code. The error detection/correction circuit 126 may be implemented using various code decoders. For example, the error detection/correction circuit 126 may be implemented with a decoder that performs nonsystematic code decoding or a decoder that performs systematic code decoding.

A bus 127 may be configured to provide a channel between the constituent elements 121, 122, 124, 125, and 126 of the memory controller 120. The bus 127 may include, for example, a control bus for delivering various kinds of control signals and commands, and a data bus for delivering various kinds of data.

Some of the elements of the above-mentioned constituent elements 121, 122, 124, 125, and 126 of the controller 120 may be omitted, or some of these elements may be integrated into a single element. Depending on cases, the memory controller 120 may also contain one or more other elements in addition to the elements identified above.

Elements of the storage device 100 may operate on the basis of an operation clock and a clock obtained by scaling down the operation clock. In addition, the controller 120 may perform a thermal throttling operation to protect elements of the storage device 100 when an internal temperature of the storage device 100 rises because of excessive heat generated by internal operations of the storage device 100. The controller 120 may reduce the velocity of the operation clock to a preset value when the controller 120 performs a thermal throttling operation. When the controller 120 starts the thermal throttling operation, the velocity of the operation clock of the storage device 100 is reduced, and performance may deteriorate. Moreover, the controller 120 reduces the velocity of the clock sharply based on an internal temperature measured by the temperature sensor regardless of operation load, and as a result an inefficient situation may occur. In addition, because the difference in performance between a case where the thermal throttling operation is performed and a case where the thermal throttling operation is not performed may be substantial, a latency experienced by the external device 150 may be long, or a timeout, in which a command provided by the external device 150 is not completed within a given time, may occur. Further, there is no method for proactively managing temperature to prevent temperatures from increasing excessively when the temperature of a storage device 100 increases gradually.

Accordingly, the present disclosure proposes a method for changing the operation clock according to temperature, which may prevent a sharp performance deterioration of the storage device 100 by proactively preventing a temperature rise. In addition, the present disclosure proposes a method for setting an optimized operation clock according to temperature based on a genetic algorithm.

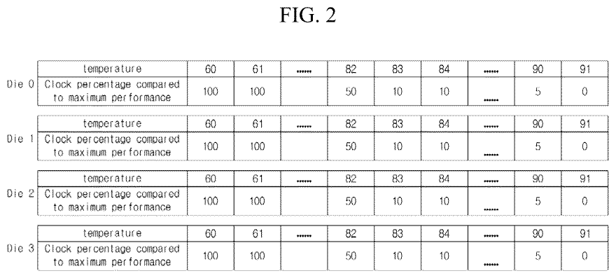

FIG. 2 is a view illustrating an operation clock according to an initially set temperature according to embodiments of the present disclosure.

Referring to FIG. 2, operation characteristics may be different for each die of a memory 110, and therefore the velocity or frequency of an operation clock set according to temperature may be different per die. Therefore, data representing the velocity of the operation clock according to temperature may be stored in a separate memory region per die. However, as illustrated in FIG. 2, the velocity of the operation clock according to temperature may be set to be the same for each die initially or at the time of product shipment. In FIG. 2, when the temperature is 60 degrees and 61 degrees, the maximum velocity of the operation clock that allows the corresponding die to provide maximum performance may be set. For example, maximum velocity may be set so that when the temperature of the die increases to 82 degrees, the clock velocity may be reduced to 50% of the maximum velocity of the operation clock, and when the temperature thereof reaches 83 degrees, the clock velocity may be reduced to 10% of the maximum velocity of the operation clock. In addition, when the temperature of the die reaches 90 degrees, the clock velocity may be reduced to 5% of the maximum velocity of the operation clock, and when the temperature of the die reaches 91 degrees, the operation of the corresponding die may stop. Although not illustrated in FIG. 2, according to embodiments, maximum velocity may be set such that when the temperature of the die is between 61 degrees and 82 degrees, the velocity of the operation clock may be set to be in reverse proportion to the temperature rise. That is, when the temperature of the die is 61 degrees or less, the maximum velocity of the operation clock may be used, and as the temperature of the die increases, the velocity of the operation clock may be reduced linearly at a constant gradient until 82 degrees, and when the temperature of the die reaches 83 degrees, the velocity of the operation clock may be sharply reduced.

FIG. 2 illustrates setting of the operation temperature of the dies as an example, however, it is apparent that the controller 120 of the storage device 100 or other electronic device may operate to set the operation temperature in similar ways that will be described below.

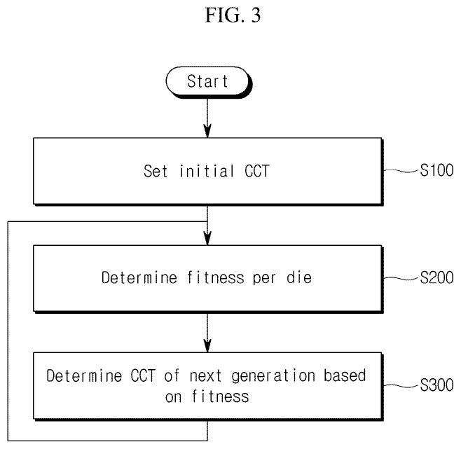

A genetic algorithm is an optimization method of finding an optimal solution by imitating a form of an organism that adapts itself to an environment and evolves, and the present disclosure proposes a method based on principles of a genetic algorithm as illustrated in FIG. 3 to find an optimized operational clock velocity according to the temperature.

FIG. 3 is a flowchart illustrating a method for optimizing a clock control table according to embodiments of the present disclosure.

In FIG. 3, a method for optimizing a clock control table may be performed by a processor 124 in FIG. 1 or an electronic device. Here, optimizing the clock control table may mean determining the operation clock at different temperatures for each die that provides the maximum performance of each die at the different temperatures.

Referring to FIG. 3, in an operation S100, an initial clock control table (CCT) may be set. The initial CCT may be a table representing the operation clock according to the temperature per die as illustrated in an example of FIG. 2. According to an embodiment, the initial clock control table may have the same settings for each die.

According to another embodiment, the processor 124 may perform an initial setting by reading the CCT stored in a memory 110 or other non-volatile memory. In this case, previous operations resulting in changes to the CCT may have been stored, and an initial CCT set at S100 may be set using stored information, with different values for each die.

Referring to FIG. 3, the processor 124 may find an optimized operation clock according to the temperature of each die by repeating determining fitness plotting per die (S200), and determining the CCT of next generation dies based on the determined fitness per die (S300). Here, the fitness may plot, as a function of a latency, a time taken from a time point when an operation for accessing each die starts to a time point when the operation ends. The latency relates to the performance of each die, and when the latency is long, it corresponds to reduction of a data amount that each die reads or writes, and that may mean that the performance deteriorates. Therefore, the fitness is a function proportional to an inverse number of the latency, and may be a value in proportion to the access performance of each die.

According to an embodiment, the processor 124 may perform a process of determining fitness per die (S200), and the determining the CCT for dies in the next generation based on the determined fitness per die (S300) at a preset cycle or a preset temperature measurement cycle. For example, when the preset cycle is 1 day or the preset temperature measurement cycle is 1 day, the processor 124 may perform each of operations S200 and S300 once a day.

According to another embodiment, the cycle at which operations S200 and S300 are repeated may be different according to the measured temperature. For example, when an average temperature of each die is low, a cycle of repeating the operations S200 and S300 may become longer, and when an average temperature of each die is relatively high, the cycle of repeating the operations S200 and S300 may become relatively shorter.

According to still another embodiment, the processor 124 may perform the determining fitness per die (S200) based on a time point when at least one among dies reaches a certain temperature. For example, when the set certain temperature is 70 degrees, the fitness of all dies may be determined at a time point when the temperature of the at least one die measured by the temperature sensor reaches 70 degrees. In this case, the operation S300 may be performed immediately after the fitness of all dies is determined.

According to still another embodiment, the processor 124 may perform the determining fitness per die (S200) at a different time point per die. For example, the processor 124 may determine fitness of a die at the time point when it reaches a threshold temperature and repeat the determination for each die when it reaches that threshold temperature. Because the time points when dies reach the threshold temperature may be different from one another, the time point for determining the fitness per die may be different from one another as well. In this case, the operation S300 may be performed at a preset cycle regardless of the fulfillment of the operation S200, and alternatively, the operation S300 may be performed after recognizing that the fitness with respect to all dies is updated.

According to still another embodiment, the processor 124 may measure a temperature of each die at a preset cycle, and when at least one among the measured temperatures corresponds to a preset temperature, the processor 124 may determine the fitness of all dies and perform the operation S300.

According to still another embodiment, the processor 124 may measure the temperature of each die at a preset cycle, and may determine the fitness of a single die with a measured temperature that corresponds to the preset temperature. In addition, the processor 124 may perform the operation S300 at the preset cycle or at a first encountering time point at the preset cycle after the fitness of all dies is updated.

According to an embodiment, the operations S200 and S300 may be repeated continuously until the power supply to the storage device 100 is stopped, and a changed CCT may be stored in the memory 110 or the other non-volatile memory whenever the CCT is changed.

According to still another embodiment, it is possible to allow the CCT to reside in a working memory 125, and when setting the initial CCT in the operation S100, the processor 124 may read the CCT stored in the memory 110 or the other non-volatile memory and store the read CCT in the working memory 125. Further, whenever the CCT is determined, it is possible to update the CCT stored in the working memory 125 with any determined values. In addition, when the power supply to the storage device 100 is stopped, or at a constant cycle, it is possible to store the CCT residing in the working memory 125 in the memory 110 or the other non-volatile memory.

According to an embodiment, when operations S200 and S300 are performed after the power supply is stopped and then resupplied, operations S200 and S300 may be performed using a CCT stored in the memory previously obtained through the genetic algorithm process conducted during an earlier power cycle. Thus, in this method previous information obtained using a genetic algorithm may continue to be used.

According to another embodiment, when operations S200 and S300 are performed after the power supply is stopped and then resupplied, an initial CCT that was input initially may be used. That is, when information obtained using genetic algorithms from previous power cycles is lost, and restarting using initial CCT information may be possible.

According to various embodiments, in operation S200, the processor 124 may determine the fitness of each die based on an average of latencies of input/output commands measured for a certain period or based on a preset number of input/output commands, a latency of a read operation or a program operation performed by the processor 124, or an average of the latencies described above.

Here, the measurement period may be determined in various ways. According to an embodiment, the measurement period may be a period according to a preset cycle. According to another embodiment, the measurement period may be a period that lasts until the number of the fulfillment of the input/output command equals to or greater than a preset value. According to another embodiment, the measurement period may be a period until a smallest value of the number of input/output commands fulfilled. with respect to a given die, equals or is greater than a preset value. According to still another embodiment, the measurement period may be a period that lasts until the number input/output command fulfilled within a certain temperature range equals or is greater than a preset value.

According to another embodiment, a length of the measurement period may not be regular and may change. According to an embodiment, a length of the measurement period may change based on a change amount of a temperature and the number of changes of temperature of each die. For example, when the change amount of a temperature is large, the length of the measurement period may be longer, and when the change amount of a temperature is small, the length of the measurement period may be shorter. In addition, when the number of changes of the measured temperature is greater compared to previous measurements, it is possible to make the length of the measurement period longer, and when the number of changes of the measured temperature is shorter, it is possible to make the length of the measurement period shorter. In addition, according to still another embodiment, it is possible to change the length of the measurement period based on an average change amount obtained by dividing the change amount of the measured temperature by the number of changes in temperature. For example, when the average change amount is larger, it is possible to make the length of the measurement period longer, and when the average change amount is shorter, it is possible to make the length of the measurement period shorter.

In addition to the above-described embodiments, in other embodiments the measurement period may be set in various ways.

The processor 124 may perform a read operation or a program operation with respect to the memory 110 based on an input/output command, that is, a read command or a program command, received from an external device 150 during the set measurement period. The processor 124 may determine a latency as the time taken from a time point when a read command is received from the external device 150 to a time point when read data is transmitted from the memory 110 to the external device 150. In addition, the processor 124 may determine a latency as the time taken from a time point when the program command is received from the external device 150 to a time point when data recording in the memory 110 is completed and a message informing that data recording is completed has been transmitted to the external device 150.

The processor 124 may determine that a latency is the time taken from a time point when starting a read operation or a program operation based on a read command or a program command from the external device 150 to a time point when the fulfillment of the read operation or the program operation ends. In addition, the processor 124 may determine that a latency is the time from a time point when performing a read operation or a program operation with respect to data of a target length to a time point when fulfillment of the read operation or the program operation ends.

The processor 124 may determine a first time, which is a period from a time point when performing a read operation or a program operation to a time point when the read operation or the program operation ends. A first value may be obtained by dividing a size of data used in the corresponding read operation or the program operation by a reference size (e.g., a data size corresponding to one strip). A latency may be determined by dividing the first time by the first value, and the latency may correspond to a latency in a case of transmitting a data of a reference size.

According to an embodiment, the processor 124 may determine fitness by only using a latency with respect to a read command. According to another embodiment, the processor 124 may determine fitness by only using a latency with respect to a program command. According to still another embodiment, the processor 124 may determine fitness by using a latency with respect to a read command and a program command.

According to an embodiment, the processor 124 may determine fitness by using a latency with respect to a read command and/or a program command performed in a certain temperature range.

According to an embodiment, the processor 124 may determine fitness by using a latency with respect to a read command and/or a program command performed with respect to data of a threshold or target size.

The processor 124 may control a read operation or a program operation in each die of the memory to be performed with an operation clock corresponding to a currently measured temperature of a die based on the CCT.

The processor 124 may determine fitness F by obtaining an average E (x) of the latencies based on an Equation 1 and obtaining an inverse number of the average based on an Equation 2. Accordingly, as the latency becomes longer, the fitness decreases, and as the latency becomes shorter, the fitness increases. Therefore, the higher the fitness, the shorter the latency and better performance.

$$E ( x ) = \frac{1}{N} {\sum }_{i = 1}^{N} latency ( i ) \qquad [ Equation 1 ]$$

Here, N represents a quantity of the latencies measured per die, and the latency i represents an i-th latency.

$$F = 1 / E ( x ) \qquad [ Equation 2 ]$$

According to various embodiments of the present disclosure, in operation S300, the processor 124 may determine the CCT for next generation dies based on the determined fitness per die.

The processor 124 may determine the fitness per die based on an average of the latencies of performed input/output commands or an average of the latencies of input/output commands measured for a certain period.

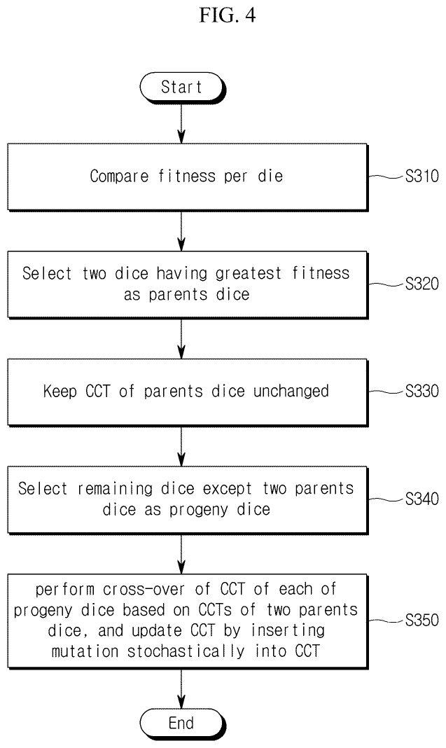

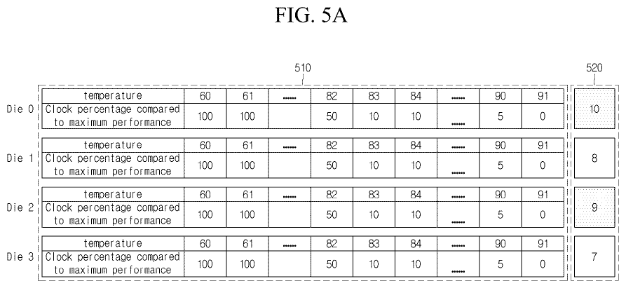

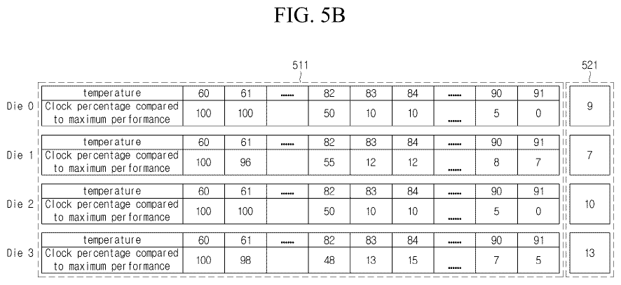

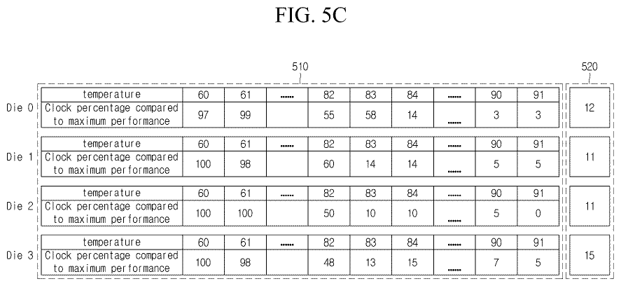

FIG. 4 is a flowchart illustrating a method for updating a clock control table based on fitness according to various embodiments of the present disclosure, and FIGS. 5A to 5C are views illustrating examples of updating a clock control table based on fitness obtained as a result of applying a method of FIG. 4.

Referring to FIGS. 4 and 5A, in an operation S310, a processor 124 may compare the fitness per die determined in an operation S200 of FIG. 3, and as a result, may select two dies having the highest fitness as parent dies in an operation S320. Referring to an example illustrated in FIG. 5A, the processor 124 may compare fitness 520 with respect to dies 0 to 3, and may select dies 0 and 2 having the highest fitness as the parent dies.

In an operation S330, the processor 124 may keep the CCT of two dies selected as the parent dies unchanged. Referring to FIGS. 5A and 5B, when comparing the CCTs 510 and 511 of the die 0 and the die 2, it can be seen that they are kept unchanged.

In an operation S340, the processor 124 may select remaining dies, except for the two parent dies, as progeny dies, and in an operation S350, the processor 124 may perform cross-over of the CCT of each of the progeny dies based on the CCTs of two parents dies, and may update the CCT by inserting a mutation stochastically into the CCT.

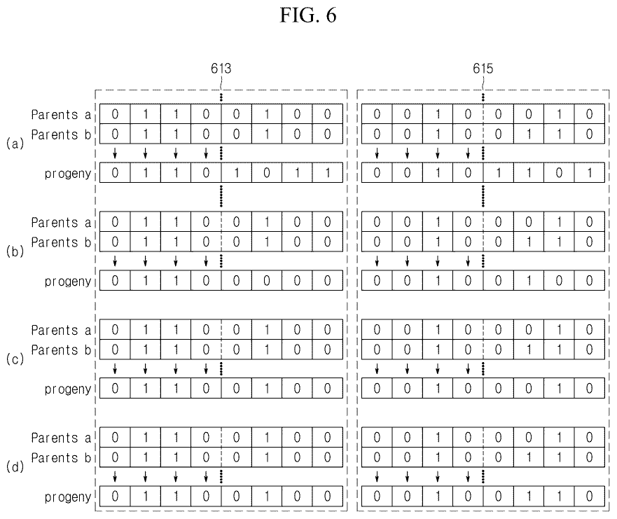

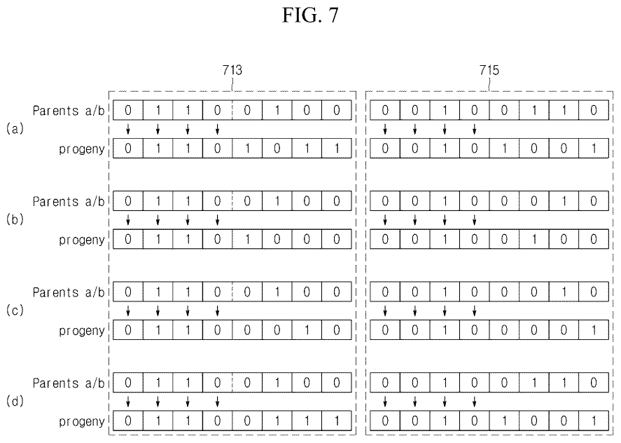

FIGS. 6 and 7 are views illustrating examples of cross-overs according to various embodiments of the present disclosure.

FIGS. 6 and 7 illustrate examples of cross-overs, however, cross-overs are not limited thereto, and a random manner of generating the CCT of progeny dies based on the CCT of two parent dies may be selected.

FIGS. 6 and 7 illustrate an operation clock of progeny dies obtained when applying various cross-over methods to the operation clock of the parent dies. As illustrated in FIGS. 5A to 5C, in order to represent the operation clock with respect to each temperature, a percentage of the operation clock which must be used compared to the operation clock to provide maximum performance for a temperature is included in the CCT. For example, when a corresponding value of the CCT at a temperature of 82 degrees is 50, a frequency of the operation clock used at a temperature of 82 degrees is a clock of 50% (e.g., 500 MHz) of the operation clock at maximum performance (e.g., 1 GHZ).

Referring to FIGS. 5A to 5C, values in the CCT in correspondence with each temperature may be a value between 0 and 100. The value may be expressed in 7-bits in a binary system. For example, 100 may be expressed as 2′b01100100, and 34 may be expressed as 2′b00100010. Here, 2′b shows that the value is expressed in a binary system. Moreover, the cross-over may be the fulfillment of an arithmetic operation with respect to the operation clock of the parent dies a and b, expressed in a binary system.

FIGS. 6 and 7 represent a cross-over with respect to first parents a and b, with results illustrated at 613 and 713, and a cross-over with respect to second parents a and b, with results illustrated at 615 and 715.

In FIGS. 6 and 7, a value representing an operation clock of the first parents a and b is 100, which is expressed as 2′b01100100 by the binary system. Values representing the operation clock of the second parents a and b are 34 and 38, and the values are expressed as 2′b00100010 and 2′b00100110, respectively, in the binary system.

Referring to (a) of FIG. 6, in a first example of a cross-over a NAND calculation per bit is performed. The NAND calculation is an equation in which a resulting value is 0 when both two bits are 1 and 1 in remaining cases. According to an embodiment, the calculation can be performed only with respect to k least significant bits (e.g., 4) because, in order to be significant, a change of one among 8-k most significant bits may be large enough to damage the stability of the calculations. In an example (a) of 613 in FIG. 6, when both first parents a and b have a value of 2′b01100100 (a decimal number 100), a result 2′b01101011 (a decimal number 107) may be obtained as the operation clock value of the progeny dies by performing a NAND calculation with respect to 4 least significant bits of 2′b01100100 (a decimal number 100). Referring to example (a) of 615 in FIG. 6, when each of the second parents a and b has a value of 2′b00100010 (a decimal number 34) and 2′b00100110 (a decimal number 38), respectively, a result 2′b00101101 (a decimal number 43) may be obtained as the operation clock value of the progeny dies by performing a NAND calculation with respect to 4 least significant bits of each of 2′b00100010 (a decimal number 34) and 2′b00100110 (a decimal number 38). In disclosed embodiments, when the obtained value is greater than 100, the value may be set as 100.

Referring to (b) of FIG. 6, a second example of a cross-over method is performing an XOR calculation per bit. The XOR calculation is an equation in which a value is 1 when two bits are different, and a value is 0 when two bits are the same. According to an embodiment, the calculation may be performed only with respect to k least significant bits for the sake of stability of the calculations. In an example (b) in 613 in FIG. 6, when both first parents a and b have a value of 2′b01100100 (a decimal number 100), a result 2′b01100000 (a decimal number 96) may be obtained as the operation clock value of the progeny dies by performing an XOR calculation with respect to 4 least significant bits of 2′b01100100 (a decimal number 100). Referring to example (b) of 615 in FIG. 6, when each of the second parents a and b have a value of 2′b00100010 (a decimal number 34) and 2′b00100110 (a decimal number 38), respectively, a result 2′b00100100 (a decimal number 36) may be obtained as the operation clock value of the progeny dies by performing an XOR calculation with respect to 4 least significant bits of each of 2′b00100010 (a decimal number 34) and 2′b00100110 (a decimal number 38). In disclose embodiments, when the obtained value is greater than 100, the value may be set as 100.

Referring to (c) of FIG. 6, a third example of the cross-over method is performing an AND calculation per bit. The AND calculation is an equation in which a value thereof is 1 only when both two bits are 1, and the value is 0 in the remaining cases. According to an embodiment, the calculation may be performed only with respect to k least significant bits for the sake of stability of the calculations. In an example (c) of 613 in FIG. 6, when both first parents a and b have a value of 2′b01100100 (a decimal number 100), a result 2′b01100100 (a decimal number 100) may be obtained as the operation clock value of the progeny dies by performing an AND calculation with respect to 4 least significant bits of 2′b01100100 (a decimal number 100). Referring to example (c) of 615 in FIG. 6, when each of the second parents a and b have a value of 2′b00100010 (a decimal number 34) and 2′b00100110 (a decimal number 38), respectively, a result 2′b00100010 (a decimal number 34) may be obtained as the operation clock value of the progeny dies by performing an AND calculation with respect to 4 least significant bits of each of 2′b00100010 (a decimal number 34) and 2′b00100110 (a decimal number 38). In disclosed embodiments, when the obtained value is greater than 100, the value may be set as 100.

Referring to (d) of FIG. 6, a fourth example of a cross-over method is performing an OR calculation per bit. The OR calculation is an equation in which a value thereof is O only when both two bits are 0, and the value is 1 in the remaining cases. According to an embodiment, the calculation may be performed only with respect to k least significant bits for the sake of stability of the calculations. In an example (d) of 613 in FIG. 6, when both first parents a and b have a value of 2′b01100100 (a decimal number 100), a result 2′b01100100 (a decimal number 100) may be obtained as the operation clock value of the progeny dies by performing an OR calculation with respect to 4 least significant bits of 2′b01100100 (a decimal number 100). Referring to example (d) of 615 in FIG. 6, when each of the second parents a and b have a value of 2′b00100010 (a decimal number 34) and 2′b00100110 (a decimal number 38), respectively, a result 2′b00100110 (a decimal number 38) may be obtained as the operation clock value of the progeny dies by performing an OR calculation with respect to 4 least significant bits of each of 2′b00100010 (a decimal number 34) and 2′b00100110 (a decimal number 38). In disclosed embodiments, when the obtained value is greater than 100, the value may be set as 100.

Referring to (a) of FIG. 7, a fifth example of a cross-over method is performing a NOT calculation per bit with one of the two parent dies a and b. The NOT calculation is an equation in which a value thereof is changed to 1 when a bit is 0, and the value is changed to 0 when a bit is 1. According to an embodiment, the calculation may be performed only with respect to k least significant bits for the sake of stability of the calculations. In an example (a) of 713 in FIG. 7, when both first parent dies a and b have a value of 2′b01100100 (a decimal number 100), a result 2′b01101011 (a decimal number 107) may be obtained as the operation clock value of the progeny dies by performing the NOT calculation with respect to 4 least significant bits of the first parent die a. Referring to example (a) of 715 in FIG. 7, when each of the second parents a and b have a value of 2′b00100010 (a decimal number 34) and 2′b00100110 (a decimal number 38), respectively, a result 2′b00101001 (a decimal number 41) may be obtained as the operation clock value of the progeny dies by performing a NOT calculation with respect to 4 least significant bits of the second parent die b. In disclosed embodiments, when the obtained value is greater than 100, the value may be set as 100.

Referring to (b) of FIG. 7, a sixth example of a cross-over method is performing a 1-bit left shift calculation per bit with one among the parent dies a and b. According to an embodiment, the calculation may be performed only with respect to k least significant bits for the sake of stability of the calculations. In an example (b) of 713 in FIG. 7, when the first parent dies a and b have a value of 2′b01100100 (a decimal number 100), a result 2′b01101000 (a decimal number 104) may be obtained as the operation clock value of the progeny dies by performing the 1-bit left shift calculation with respect to 4 least significant bits of the first parent die a. Referring to example (b) of 715 in FIG. 7, when each of the second parents a and b have a value of 2′b00100010 (a decimal number 34) and 2′b00100110 (a decimal number 38), respectively, a result 2′b00100100 (a decimal number 36) may be obtained as the operation clock value of the progeny dies by performing the 1-bit left shift calculation with respect to 4 least significant bits of the second parent die a. In disclosed embodiments, when the obtained value is greater than 100, the value may be set as 100.

Referring to (c) of FIG. 7, a seventh example of a cross-over method is performing a 1-bit right shift calculation per bit with one among the parent dies a and b. According to an embodiment, the calculation may be performed only with respect to k least significant bits for the sake of stability of the calculations. In an example (c) of 713 in FIG. 7, when the first parent dies a and b have a value of 2′b01100100 (a decimal number 100), a result 2′b01100010 (a decimal number 98) may be obtained as the operation clock value of the progeny dies by performing the 1-bit right shift calculation with respect to 4 least significant bits of the first parent die a. Referring to example (c) of 715 in FIG. 7, when each of the second parents a and b have a value of 2′b00100010 (a decimal number 34) and 2′b00100110 (a decimal number 38), respectively, 2′b00100001 (a decimal number 33) may be obtained as the operation clock value of the progeny dies by performing the 1-bit right shift calculation with respect to 4 least significant bits of the second parent die a. In disclosed embodiments, when the obtained value is greater than 100, the value may be set as 100.

Referring to (d) of FIG. 7, an eighth example of a cross-over method is performing a calculation of adding a random value to a selected one among the parent dies a and b. According to an embodiment, the calculation may be performed only with respect to k least significant bits for the sake of stability of the calculations. In an example (d) of 713 in FIG. 7, when both first parent dies a and b have a value of 2′b01100100 (a decimal number 100), a result 2′b01100111 (a decimal number 103) may be obtained as the operation clock value of the progeny dies by performing the calculation of adding a random value with respect to 4 least significant bits of the first parent die a. Referring to example (d) of 715 in FIG. 7, when each of the second parents a and b have a value of 2′b00100010 (a decimal number 34) and 2′b00100110 (a decimal number 38), respectively, a result 2′b00101001 (a decimal number 41) may be obtained as the operation clock value of the progeny dies by performing the calculation of adding a random value (e.g., 3) with respect to 4 least significant bits of the second parent die b. In disclosed embodiments, when the obtained value is greater than 100, the value may be set as 100.

Similar to a manner proposed in (d) of FIG. 7, a calculation of subtracting a random value may be possible and a cross-over method combining the above-described plurality of calculations may be selected. Therefore, a random manner of changing 4 least significant bits of 8-bit data representing the operation clock may be applied as the cross-over manner apart from the above-described manners.

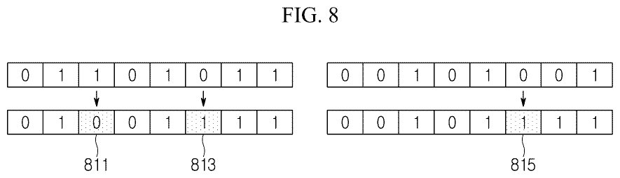

FIG. 8 is a view illustrating an example of a mutation according to embodiments of the present disclosure.

Referring to FIG. 8, whether a mutation occurs may be determined after determining the operation clock value by applying a cross-over with respect to the progeny dies. According to an embodiment, a mutation may occur with a preset probability (e.g., 0.02). When the mutation occurs, values of bits (811, 813, 815) in which a mutation occurs, represented in hash in FIG. 8, may be inverted. That is, 0 may be inverted into 1, and 1 may be inverted into 0. The mutation may occur in entire bits, rather than the 4 least significant bits. In addition, when a value changes to a value greater than 100 because of a mutation, the value may be set as 100.

Referring back to FIG. 4, in operation S350, a processor 124 may update a CCT of the progeny dies using above-described cross-overs and mutation. The processor 124 may use cross-over methods that are different for each progeny die. In addition, the processor 124 may apply a plurality of cross-over manners sequentially.

Referring back to FIG. 3, in operation $300, one generation may go by, by determining the CCT of the next generation based on fitness. Thereafter, the processor 124 may wait for the next time point for updating the next CCT, and may update the CCT again by performing operations S200 and S300 when the time point for update arrives. In successive generations, the CCTs are updated based on values of CCTs having excellent fitness, and it becomes possible to find more optimized values.

In the above-described embodiments, operations for establishing a CCT with respect to for operating temperatures and updating the CCTs have been described, however, it is possible to generate a separate CCT for a temperature section, and to update the CCT according to the temperature section. In this case, the processor 124 may obtain and apply the fitness per temperature section.

Lastly, the processor 124 or the controller 120 may obtain the operation temperature of the current die, and determine the operation clock with respect to the corresponding die based on the obtained operation temperature of the die and an updated CCT.

As described above, the present disclosure has proposed a measure for having a different operation clock to use according to the operation temperature per die of the memory, and a measure for applying genetic algorithms to find an optimized operation clock according to the operation temperature per die. As a result, a sudden performance deterioration caused by the conventional thermal throttling entrance may be prevented and finally, the thermal throttling entrance may be reduced.

What is claimed is:

1. A memory controller, comprising:
a first interface configured to perform a data communication with a first external device;
a second interface configured to generate a signal controlling an operation of a second external device; and
at least one processor configured to determine an operation clock of the second external device based on a temperature of the second external device.

2. The memory controller of claim 1,
wherein the at least one processor sets a clock control table of which an operation clock according to a temperature is set with respect to each of a plurality of dies provided in the second external device;
determines fitness corresponding to performance of each die with respect to each of the plurality of dies; and
updates the clock control table based on the fitness determined with respect to each of the plurality of dies.

3. The memory controller of claim 2,
wherein the at least one processor determines the fitness with respect to each of the plurality of dies whenever a preset condition is satisfied, and updates the clock control table based on the fitness determined with respect to each of the plurality of dies.

4. The memory controller of claim 2,
wherein the at least one processor measures a latency, which is a time period from a time point when fulfillment of a read operation or a program operation starts to a time point when the fulfillment is completed per the plurality of dies; and
determines an inverse number of the latency by using the fitness with respect to each of the plurality of dies.

5. The memory controller of claim 2,
wherein the at least one processor measures a latency, which is a time period from a time point when fulfillment of a read operation or a program operation starts to a time point when the fulfillment is completed per the plurality of dies, for a plurality of times for a certain period;
determines an average latency by averaging a plurality of latencies measured per the plurality of dies for the certain period; and
determines an inverse number of the average latency by using the fitness with respect to each of the plurality of dies.

6. The memory controller of claim 5,
wherein the at least one processor changes the certain period based on a change amount of a measured temperature and/or a number of times of a change of a measured temperature.

7. The memory controller of claim 2,
wherein the at least one processor compares the fitness determined with respect to each of the plurality of dies;
selects two dies having highest fitness among the plurality of dies as parent dies;
keeps the clock control table unchanged with respect to the parent dies;
selects remaining dies except the parent dies among the plurality of dies as progeny dies; and
updates the clock control table of the progeny dies based on the clock control table of the parent dies.

8. The memory controller of claim 7,
wherein the at least one processor updates the clock control table of the progeny dies by cross-over of the clock control table of the parent dies.

9. The memory controller of claim 8,
wherein the at least one processor additionally updates the clock control table of the progeny dies by inserting a mutation stochastically into the clock control table of the progeny dies.

10. The memory controller of claim 8,
wherein the at least one processor performs the cross-over by performing a bitwise operation on two values corresponding to an operation clock set per temperature in the clock control table of the parent dies; and
wherein the bitwise operation is one among a NAND calculation per bit, an XOR calculation per bit, an AND calculation per bit, and an OR calculation per bit.

11. The memory controller of claim 8,
wherein the at least one processor performs the cross-over by selecting one among two values corresponding to an operation clock set per temperature in the clock control table of the parent dies and by performing a bitwise operation on the selected one value, and
wherein the bitwise operation is one among a NOT calculation per bit, a calculation of a bit left shift as many as a preset quantity of bits, a calculation of bit right shift as many as a preset quantity of bits, a calculation of adding a preset first value, and a calculation of subtracting a preset second value.

12. The memory controller of claim 10,
wherein the at least one processor performs the cross-over by performing the bitwise operation only on a preset number of least significant bits among a plurality of bits representing a value corresponding to the operation clock, and by keeping remaining bits unchanged.

13. The memory controller of claim 9,
wherein the at least one processor determines whether to insert the mutation with respect to each of a plurality of bits representing a value corresponding to the operation clock based on a preset probability; and
inverts a bit value of the bit determined to be inserted with the mutation.

14. A method for operating a memory controller, comprising:
setting a clock control table of which an operation clock according to a temperature is set with respect to each of a plurality of dies provided in a memory;
determining fitness corresponding to performance of each die with respect to each of the plurality of dies; and
updating the clock control table based on the fitness determined with respect to each of the plurality of dies.

15. The method for operating a memory controller of claim 14,
wherein the determining fitness with respect to each of the plurality of dies includes:
measuring a latency, which is a time from a time point when fulfillment of a read operation or a program operation starts to a time point when the fulfillment is completed per the plurality of dies; and
determining an inverse number of the latency by using the fitness with respect to each of the plurality of dies.

16. The method for operating a memory controller of claim 14,
wherein the determining fitness with respect to each of the plurality of dies includes:
measuring a latency, which is a time from a time point when fulfillment of a read operation or a program operation starts to a time point when the fulfillment is completed per the plurality of dies, for a plurality of times for a certain period;
determining an average latency by averaging a plurality of latencies measured per the plurality of dies for the certain period; and
determining an inverse number of the average latency by using the fitness with respect to each of the plurality of dies.

17. The method for operating a memory controller of claim 14,
wherein the updating the clock control table based on the fitness determined with respect to each of the plurality of dies includes:
comparing the fitness determined with respect to each of the plurality of dies;
selecting two dies having highest fitness among the plurality of dies as parent dies;
keeping the clock control table unchanged with respect to the parent dies;
selecting remaining dies except the parent dies among the plurality of dies as progeny dies; and
updating the clock control table of each of the progeny dies based on the clock control table of the parent dies.

18. A storage device, comprising:
a memory having a plurality of dies; and
a memory controller configured to generate a signal controlling an operation of the memory and to determine an operation clock of each of the plurality of dies based on a temperature of each of the plurality of dies,
wherein the memory controller sets a clock control table of which an operation clock according to a temperature per the plurality of dies is set;
determines fitness corresponding to performance of each die with respect to each of the plurality of dies; and
updates the clock control table based on the fitness determined with respect to each of the plurality of dies.

19. The storage device of claim 18,
wherein the memory controller measures a latency, which is a time from a time point when fulfillment of a read operation or a program operation starts to a time point when the fulfillment is completed per the plurality of dies; and
determines an inverse number of the latency by using the fitness with respect to each of the plurality of dies.

20. The storage device of claim 18,
wherein the memory controller measures a latency, which is a time from a time point when fulfillment of a read operation or a program operation starts to a time point when the fulfillment is completed per the plurality of dies, a plurality of times for a certain period;
determines an average latency by averaging a plurality of latencies measured per the plurality of dies for the certain period; and
determines an inverse number of the average latency by using the fitness with respect to each of the plurality of dies.
